(19) United States
(12) Patent Application Publication
(10) Pub. No.: US 2016/0351777 A1
(43) Pub. Date: Dec. 1, 2016

(54) THERMOELECTRIC GENERATION DEVICE FOR VEHICLE

(71) Applicant: HYUNDAI MOTOR COMPANY, Seoul (KR)

(72) Inventors: Jin Woo KWAK, Gyeongsan-si (KR); ln Woong LYO, Suwon-si (KR); Su Jung NOH, Seoul (KR); In Chang CHU, Seoul (KR); Seung Woo LEE, Seoul (KR); Han Saem LEE, Seoul (KR)

(73) Assignee: HYUNDAI MOTOR COMPANY, Seoul (KR)

(21) Appl. No.: 14/934,649

(22) Filed: Nov. 6, 2015

(30) Foreign Application Priority Data
Jun. 1, 2015 (KR) 10-2015-0077053

(51) Int. Cl. H01L 35/32; H01L 35/30

(52) U.S. Cl. CPC H01L 35/32; H01L 35/30

(57) ABSTRACT

A thermoelectric generation device using engine waste heat includes: a thermoelectric element including a sheet-type graphite layer having thermal conductivity; first heat transfer bodies joined to the graphite layer at intervals and having thermal conductivity and electrical conductivity; second heat transfer bodies disposed between the first heat transfer bodies at intervals and having thermal conductivity and electrical conductivity; first pellets of a P-type thermoelectric material joined between the first and second heat transfer bodies alternately with second pellets of an N-type thermoelectric material. The second pellets are joined between the first and second heat transfer bodies alternately with the first pellets. In particular, at least one of the first pellet or the second pellet is joined in a line-contact to form an angle with an inclined portion of the adjacent heat transfer body and to form a surface-contact when the graphite layer is curved.

### CROSS-REFERENCE TO RELATED APPLICATION

This application claims the benefit of Korean Patent Application No. 10-2015-0077053, filed on Jun. 1, 2015, which is incorporated herein by reference in its entirety.

### FIELD

The present disclosure relates to a thermoelectric generation device using waste heat of an engine which may generate electric energy.

### BACKGROUND

The statements in this section merely provide background information related to the present disclosure and may not constitute prior art.

Generally, a thermoelectric generation technique for a vehicle is a technique of generating electric energy by using a thermoelectric element which is installed together with a cooling system on a hot heat source unit (an exhaust system, an engine unit, or the like) to improve fuel efficiency, and the thermoelectric element has a characteristic in which electrons move by a thermal gradient.

In general, since thermoelectric conversion performance depends on a unique ZT value (a performance index representing a thermoelectric characteristic of a thermoelectric material) and an output is determined in proportion to a difference in temperature between a high-temperature portion and a low-temperature portion of the thermoelectric material, a thermoelectric material by determining a heat source characteristic of an applied portion, a design of the element, and a system configuration are important.

Most of the thermoelectric generation systems that have been developed for vehicles are applied to an exhaust pipe through which hot exhaust gas passes, but the thermoelectric generation systems have failed to obtain a desired high output.

Currently, in the case of thermoelectric elements and systems which have been developed for application to the exhaust pipe, heat of the exhaust gas is not efficiently transferred into the element due to various heat-transfer resistance factors which are generated in the elements or which are generated during an interface joining process to constitute a thermoelectric module or system, and heat loss to the outside is generated and thus efficiency is lowered.

As known, in the thermoelectric element, as the difference in temperature between the high-temperature portion and the low-temperature portion is large, the output is increased, and performance of the entire thermoelectric system depends on heat exchange efficiency of the cooling system.

In the case of a thermoelectric system applied to an exhaust pipe in the related art, a separate water cooling system is installed so as to enhance cooling efficiency of the low-temperature portion, and since the water cooling system includes a coolant, a heat exchanger, a motor, a flow channel, and the like, a weight and a volume of the system are largely increased.

Further, in the case of an exhaust system for a vehicle, generally, since a difference in calorific value between a front section which is relatively near to the engine and a rear section far away from the engine occurs, the efficiency of the entire system deteriorates in the case of the thermoelectric system applied to the exhaust pipe disposed at the rear section.

Meanwhile, in the case of the engine for the vehicle, a high temperature of 500° C. or more (600° C. in diesel and 800° C. or more in gasoline) is maintained, and in the case of using an engine coolant, a separate cooling system is not required, and as a result, the thermoelectric system applied to the engine is compact and light, and has high output performance as compared with the thermoelectric system applied to the existing exhaust pipe.

In order to apply the thermoelectric element to the engine, the thermoelectric element does not need to influence a catalyst activation temperature of an exhaust system disposed at the rear side of the engine, and needs to be attached to a complicated shape of the engine. Further, the output needs to be enhanced by increasing the number of thermoelectric elements which are attachable to the engine by forming a large attachment area.

The existing thermoelectric element is configured by a structure in which metal interconnects are attached to a pair of insulation substrate in a predetermined pattern and a first pellet made of a P-type thermoelectric material and a second pellet made of an N-type thermoelectric material are joined to the metal interconnects as a pair. Due to heat resistance of a soldering material for joining the pellets to the metal interconnects or joining the metal interconnects to the substrate, even though the thermoelectric material having a high ZT value at the high temperature exists, there is a limitation to develop the thermoelectric element which is applicable at the high temperature.

Further, since the substrate needs to be electrically insulated while efficiently transferring heat, a ceramic material has been frequently used, but due to characteristics of the ceramic material, the ceramic material is very vulnerable to durability for vibration, thermal shock, and the like.

### SUMMARY

The present disclosure provides a thermoelectric generation device using engine waste heat, providing advantages of generating electric energy by using hot waste heat generated in an engine and improving fuel efficiency.

In one aspect, the present disclosure provides a thermoelectric generation device using engine waste heat, including: a thermoelectric element including a sheet-type graphite layer having thermal conductivity; a plurality of first heat transfer bodies joined to one surface of the graphite layer at predetermined intervals and having thermal conductivity and electrical conductivity; a plurality of second heat transfer bodies disposed between the first heat transfer bodies at predetermined intervals and having thermal conductivity and electrical conductivity; first pellets of a P-type thermoelectric material joined adjacent to each other between the first heat transfer bodies and the second transfer bodies alternately with second pellets given below; and second pellets of an N-type thermoelectric material joined adjacent to each other between the first heat transfer bodies and the second transfer bodies alternately with the first pellets, in which at least one of the first pellet and the second pellet are joined in a line-contact form in such a manner to form an angle with an inclined portion of the adjacent heat transfer body at only one-side edge thereof to surface-contact the inclined portion of the adjacent heat transfer body when the graphite layer is curved.

In one form, the first heat transfer body and the second heat transfer body may have trapezoidal cross-sections and the first pellet and the second pellet may have parallelogram cross-sections, and the angle between the heat transfer body and the pellet may be controlled by changing and controlling a slope of at least one inclined portion of the inclined portions of the heat transfer body and pellet adjacent to each other.

In another form, the thermoelectric element may be attached to one end of the heat pipe to be surrounded in order to increase heat transfer efficiency.

In still another form, a housing receiving thermoelectric cartridges comprising the thermoelectric element and the heat pipe may be formed, the housing may be tightly divided into a compressing portion at an upper end and an evaporating portion at a lower end along a length direction of the thermoelectric cartridge, in the compressing portion, an exhaust gas inlet and an exhaust gas outlet for flowing and discharging the exhaust gas may be formed in order to flow the exhaust gas to the thermoelectric element surrounding one end of the heat pipe, and in the evaporating portion, a coolant inlet and a coolant outlet for flowing and discharging the engine coolant may be formed in order to flow the engine coolant to the other end of the heat pipe.

In yet another form, the heat pipe may be a rod-type heat exchanger in which a working fluid is sealed into a pipe portion in a vacuum state, steel use stainless (SUS) is used as a material of the pipe portion, and the working fluid uses any one material or a mixture of two or more materials selected from mercury, sodium, lithium, and silver.

According to the exemplary form of the present disclosure, the thermoelectric element is configured in a solid to solid contact form by using a shape of the pellets and the heat transfer bodies without using a separate joining (soldering) material or process for joining on the substrate as a structure without the substrate, and as a result, the thermoelectric generation in the high-temperature area such as the engine waste heat which cannot be used due to a heat-resistance characteristic of the soldering material used in the existing substrate is possible.

Other aspects and forms of the present disclosure are discussed infra.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a diagram illustrating a thermoelectric generation device according to one form of the present disclosure;

FIG. 2 is a cross-sectional view taken along line A-A of FIG. 1; and

FIG. 3 is a diagram illustrating an unfolded shape before the thermoelectric generation device is attached to a heat pipe according to the present disclosure.

It should be understood that the appended drawings are not necessarily to scale, presenting a somewhat simplified representation of various features illustrative of the basic principles of the present disclosure. The specific design features of the present disclosure as disclosed herein, including, for example, specific dimensions, orientations, locations, and shapes will be determined in part by the particular intended application and use environment.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

The present disclosure is intended to cover not only the exemplary forms, but also various alternatives, modifications, equivalents and other forms, which may be included within the spirit and scope of the present disclosure as defined by the appended claims.

In the present disclosure, the thermoelectric conversion of the high-temperature engine waste heat reaching at proximately several hundred degrees is performed via a structure which does not require a substrate and a soldering material causing a heat-resisting temperature. The removal of the soldering material for interfacial joining contributes to overcoming the problem of the heat-resisting temperature.

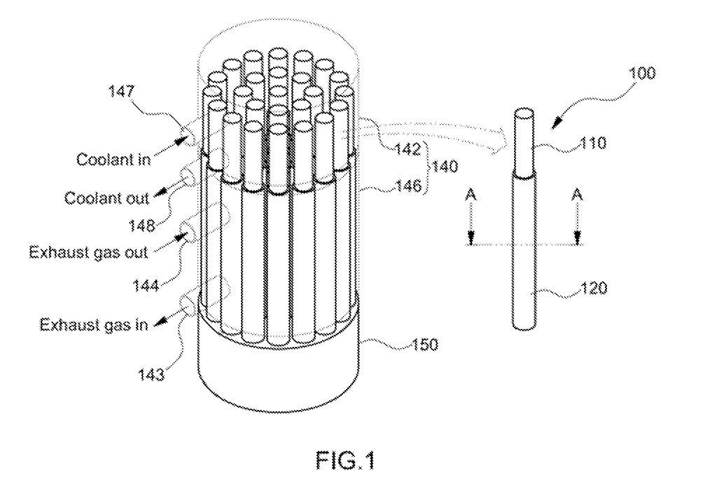

As illustrated in FIG. 1, a thermoelectric generation device according to one form of the present disclosure is configured as a thermoelectric cartridge unit which modularizes a plurality of thermoelectric cartridges 100, and each thermoelectric cartridge 100 comprises a heat pipe 110 having a rod shape and a thermoelectric element 120 attached to the lower end of the heat pipe 110.

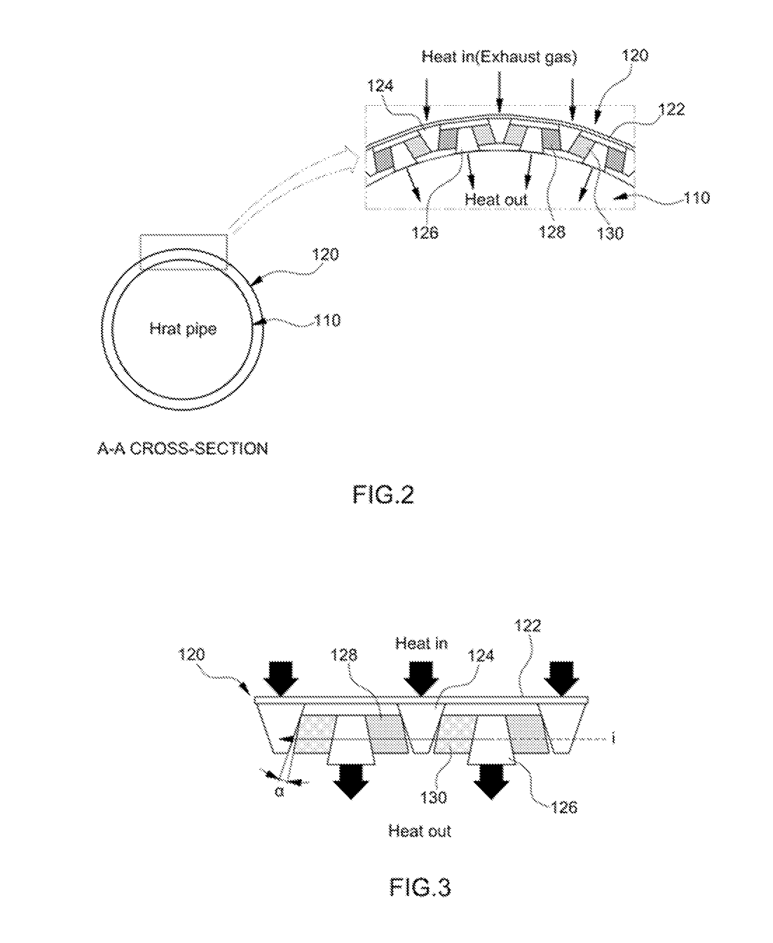

Referring to FIGS. 2 and 3, the thermoelectric element 120 includes a graphite layer 122 having thermal conductivity, a plurality of first heat transfer bodies 124 and second heat transfer bodies 126 attached onto the graphite layer 122, and a plurality of first pellets 128 and second pellets 130 disposed between the first heat transfer bodies 124 and the second heat transfer bodies 126.

The graphite layer 122 efficiently transfers heat of a heat source (exhaust gas) while preventing high-temperature oxidation of the thermoelectric element 120 by using a barrier characteristic of a graphite material, and is formed in a sheet-type which is flexibly bendable.

The first heat transfer bodies 124 have thermal conductivity for transferring the heat of the heat source and electrical conductivity for electrical conduction and are formed of hexahedrons having a parallelogram cross section, the first pellet 128 and the second pellet 130 are adjacent to an inclined portion having a predetermined slope, and a relatively wide surface of upper and lower surfaces facing each other in parallel is attached to one surface of the graphite layer 122.

In this case, the first heat transfer bodies 124 are stacked and arranged on the graphite layer 122 at regular intervals in a predetermined pattern.

The second heat transfer bodies 126 also have thermal conductivity for transferring the heat of the heat source and electrical conductivity for electrical conduction, and are disposed between the first heat transfer bodies 124 at regular intervals, and are formed of hexahedrons having a parallelogram cross section, so that the first pellet 128 and the second pellet 130 are adjacent to an inclined portion having a predetermined slope, and a relatively small surface of the upper and lower surfaces facing each other in parallel faces one surface of the graphite layer 122 at a predetermined interval.

The other relatively large surface of the upper and lower surfaces facing each other in parallel of the second heat transfer body 126 contacts the surface of the heat pipe 110 when one end of the heat pipe 110 is surrounded by the thermoelectric element 120.

In addition, the first pellets 128 are made of a P-type thermoelectric material and joined adjacent to each other so as to be inserted between the first heat transfer bodies 124 and the second heat transfer bodies 126. In this case, the first pellets 128 are attached to an inclined portion of the adjacent second heat transfer bodies 126 (alternatively, the first heat transfer bodies) in a surface-contact form, and only one edge is attached to an inclined portion of the first heat transfer bodies 124 (alternatively, the second heat transfer bodies) in a line-contact form.

The second pellets 130 are made of an N-type thermoelectric material and joined adjacent to each other so as to be inserted between the first heat transfer bodies 124 and the second heat transfer bodies 126. In this case, the second pellets 130 are attached to an inclined portion of the adjacent second heat transfer bodies 126 (alternatively, the first heat transfer bodies) in a surface-contact form, and only one edge is attached to an inclined portion of the first heat transfer bodies 124 (alternatively, the second heat transfer bodies) in a line-contact form.

That is, the first pellets 128 and the second pellets 130 are attached to both inclined portions of the second heat transfer bodies 126 (alternatively, the first heat transfer bodies) in a surface-contact form, respectively, and the only one-side edges of the first pellets 128 and the second pellets 130 are attached to both inclined portions of the first heat transfer bodies 124 (alternatively, the second heat transfer bodies) in a line-contact form, respectively.

Since the first pellets 128 and the second pellets 130 are attached to both inclined portions of the first heat transfer bodies 124 in the line-contact form, respectively, an angle α is formed between the both inclined portions of the first heat transfer bodies 124 (see FIG. 3). As a result, when the graphite layer 122 is flexibly curved to cover the heat pipe 110, the first pellets 128 and the second pellets 130 surface-contact the both inclined portions of the first heat transfer bodies 124.

Accordingly, a surface curvature of the thermoelectric element 120 may be adjusted by changing and controlling the angle α.

Since the first heat transfer bodies 124 and the second heat transfer bodies 126 have trapezoidal cross-sections and the first pellets 128 and the second pellets 130 have parallelogram cross-sections, the angle α between the heat transfer body and the pellet may be controlled by changing and controlling a slope of at least one inclined portion of the inclined portions of the heat transfer body and pellet adjacent to each other.

In addition, the first pellets 128 and the second pellets 130 are alternately disposed between the first and second heat transfer bodies 124 and 126, and PN-junction pairs forming a pair in the joined form with the heat transfer bodies therebetween are connected to each other in series. In this case, the heat transfer bodies simultaneously serve as the substrate for the existing heat transfer and the conductor for electrical conduction to generate electricity when the electrons move by a temperature gradient.

The thermoelectric element 120 configured above may surround one end of the heat pipe 110 in order to increase efficiency of heat transfer and heat exchange.

The heat pipe 110 is a rod-type heat exchanger in which a working fluid is sealed into a pipe portion (a container) in a vacuum state, and in order to use the heat pipe 110 at a high temperature such as engine waste heat, a stainless metal such as Steel Use Stainless (SUS) is used as a material of the pipe portion. In addition, the working fluid in the pipe portion uses any one material or a mixture of two or more materials selected from mercury, sodium, lithium, and silver according to a temperature range to be applied.

When one end of the heat pipe is heated, the working fluid in the pipe portion passes through a center portion of the heat pipe which is in the vacuum state, and moves to the other end in which the working fluid is compressed, and then the working fluid automatically moves back to its initial position so that heat exchange is performed by the movement of the working fluid.

As described above, the thermoelectric cartridge 100 is formed by the heat pipe 110 and the thermoelectric element 120 attached to the lower end of the heat pipe 110, and the plurality of thermoelectric cartridges 100 are modularized to constitute the thermoelectric generation device.

As illustrated in FIG. 1, the thermoelectric generation device includes a housing receiving the plurality of thermoelectric cartridges 110 inside the housing 140, and the housing 140 is tightly divided into a compressing portion 142 at an upper end and an evaporating portion 146 at a lower end along a length direction of the thermoelectric cartridge 100. Hot exhaust gas discharged from the engine is supplied to pass through the evaporating portion 146 and an engine coolant is supplied to flow into the compressing portion 142.

To this end, in the compressing portion 142, an exhaust gas inlet 143 and an exhaust gas outlet 144 for inflowing and discharging the exhaust gas are formed, and in the evaporating portion 146, a coolant inlet 147 and a coolant outlet 148 for inflowing and discharging the engine coolant are formed.

The exhaust gas flowing to the compressing portion 142 transfers heat to the thermoelectric element 120 side while passing through the outside of the thermoelectric element 120 surrounding one end of the heat pipe 110, and the engine coolant flowing to the evaporating portion 146 flows into the other end of the heat pipe 110 (a portion which is not surrounded by the thermoelectric element) to enhance thermal conductivity of the heat pipe 110.

As a result, the thermoelectric element 120 largely maintains a temperature difference between an outer side (the graphite layer and the first heat transfer bodies) receiving the heat of the exhaust gas and an inner side (the second heat transfer bodies) receiving the heat of the heat pipe 110 to emit a high output.

That is, the heat from the heat source (the exhaust gas) is transferred to the first pellets 128 and the second pellets 130 through the graphite layer 122 and the first heat transfer bodies 124, and the heat from the heat pipe 110 is transferred to the first pellets 128 and the second pellets 130 through the second heat transfer bodies 126, and as a result, the temperature difference between the outer side and the inner side of the thermoelectric element 120 is largely maintained.

In addition, an electrode unit 150 for outputting electricity generated from the thermoelectric element 120 is configured at the lower side of the housing 140.

The electrode unit 150 is electrically connected with the thermoelectric element 120 so that electricity generated from the thermoelectric element 120 may flow, and although not illustrated, the electrode unit 150 includes an electrode terminal for transmitting the electricity output from the thermoelectric element 120, a DC-DC converter, and the like to be configured as an apparatus for converting the electricity output from the thermoelectric element by thermoelectric generation to be used in an electric field load of a vehicle.

As such, in the present disclosure, the thermoelectric element 120 is configured in a solid to solid contact form by using a shape of the pellets 128 and 130 and the heat transfer bodies 124 and 126 without using a separate joining (soldering) material or process for joining on the substrate as a structure without the substrate, and as a result, the thermoelectric generation in the high-temperature area such as the engine waste heat which cannot be used due to a heat-resistance characteristic of the soldering material used in the existing substrate is possible.

Further, in the case of the thermoelectric generation, generally, when an interface such as the substrate of the thermoelectric element is generated, a thermal loss is generated and thus heat transfer efficiency is reduced. In the present disclosure, as the structure without the substrate, since the thermoelectric element 120 is directly attached to the heat pipe 110, which is the heat exchanger, through the heat transfer bodies 126 and the exhaust gas is directly transferred to the pellets 128 and 130 through the heat transfer bodies 124, the heat transfer efficiency is largely increased.

Further, when the thermoelectric element 120 is installed on the front end of a diesel engine catalyst unit, higher output is possible in that a high-temperature heat source may be supplied at all times.

Meanwhile, in the case of removing the angle α between the heat transfer bodies 124 and 126 and the pellets 128 and 230 by modifying the thermoelectric element 120 to configure a flat-type thermoelectric element, the thermoelectric element is joined onto the surface of the flat-type heat pipe through a soldering or brazing process to configure the thermoelectric cartridge, and as a result, thermoelectric generation is possible in a low-temperature area of the vehicle in addition to the engine unit.

The present disclosure has been described in detail with reference to forms thereof. However, it will be appreciated by those skilled in the art that changes may be made in these forms without departing from the principles and spirit of the present disclosure, the scope of which is defined in the appended claims and their equivalents.

What is claimed is:

1. A thermoelectric generation device using engine waste heat, comprising:
a thermoelectric element configured by a sheet-type graphite layer having thermal conductivity;
a plurality of first heat transfer bodies joined to a surface of the graphite layer at predetermined intervals and having thermal conductivity and electrical conductivity;
a plurality of second heat transfer bodies disposed between the first heat transfer bodies at predetermined intervals and having thermal conductivity and electrical conductivity; and
first pellets of a P-type thermoelectric material joined adjacent to each other between the first heat transfer bodies and the second heat transfer bodies alternately with second pellets, the second pellets of an N-type thermoelectric material joined adjacent to each other between the first heat transfer bodies and the second heat transfer bodies alternately with the first pellets;
wherein at least one of the first pellets or the second pellets is joined with an inclined portion of an adjacent heat transfer body in a line-contact form so as to form an angle with the inclined portion of the adjacent heat transfer body at one-side edge thereof, and said at least one of the first pellets or the second pellets forms a surface-contact with the inclined portion of the adjacent heat transfer body when the graphite layer is curved.

2. The thermoelectric generation device according to claim 1, wherein the first heat transfer bodies and the second heat transfer bodies each have a trapezoidal cross-section, and the first pellets and the second pellets each have a parallelogram cross-section, and wherein the angle between said at least one of the first pellets or the second pellets and the inclined portion of the adjacent heat transfer body is controlled by changing and controlling a slope of the inclined portion of the adjacent heat transfer body and the first and second pellets adjacent to each other.

3. The thermoelectric generation device according to claim 1, wherein the thermoelectric element is attached to one end of a heat pipe to be surrounded so as to increase a heat transfer efficiency.

4. The thermoelectric generation device according to claim 3, wherein a housing receives thermoelectric cartridges each comprising the thermoelectric element and the heat pipe, and the housing is divided into a compressing portion at an upper end and an evaporating portion at a lower end along a length direction of the thermoelectric cartridges,
wherein in the compressing portion, an exhaust gas inlet and an exhaust gas outlet for flowing and discharging the exhaust gas are formed so as to flow the exhaust gas to the thermoelectric element surrounding one end of the heat pipe, and in the evaporating portion, a coolant inlet and a coolant outlet for flowing and discharging an engine coolant are formed so as to flow the engine coolant to another end of the heat pipe.

5. The thermoelectric generation device according to claim 3, wherein the heat pipe is a rod-type heat exchanger in which a working fluid is sealed into a pipe portion in a vacuum state, and the working fluid uses any one material or a mixture of two or more materials selected from mercury, sodium, lithium, and silver.

6. The thermoelectric generation device according to claim 5, wherein the pipe portion is made of steel use stainless material.
